(19) United States
(12) Patent Application Publication
(10) Pub. No.: US 2019/0080999 A1
(43) Pub. Date: Mar. 14, 2019

(54) PACKAGE SUBSTRATES WITH SIGNAL TRANSMISSION PATHS RELATING TO PARASITIC CAPACITANCE VALUES

(71) Applicant: SK hynix Inc., Icheon-si Gyeonggi-do (KR)

(72) Inventors: Juil EOM, Guri-si Gyeonggi-do (KR); Sang Joon LIM, Icheon-si Gyeonggi-do (KR); Bok Kyu CHOI, Yongin-si Gyeonggi-do (KR)

(73) Assignee: SK hynix Inc., Icheon-si Gyeonggi-do (KR)

(21) Appl. No.: 15/982,441

(22) Filed: May 17, 2018

(30) Foreign Application Priority Data
Sep. 13, 2017 (KR) 10-2017-0117476

(51) Int. Cl. H01L 23/522; H05K 1/02; H01L 23/64; H05K 1/16

(52) U.S. Cl. CPC H01L 23/5223; H05K 1/0298; H05K 2201/0792; H05K 1/162; H01L 23/642

(57) ABSTRACT

A package substrate may include a first total signal path having a first parasitic capacitance value and a second total signal path having a second parasitic capacitance value different from the first parasitic capacitance value. The package substrate may include a first capacitance adjustment pattern disposed within the package substrate and configured to reduce the difference between the first and second parasitic capacitance values.

### CROSS-REFERENCE TO RELATED APPLICATIONS

The present application claims priority under 35 U.S.0 119(a) to Korean Application No. 10-2017-0117476, filed on Sep. 13, 2017, which is incorporated herein by references in its entirety.

### BACKGROUND

### 1. Technical Field

The present disclosure generally relates to semiconductor package technologies and, more particularly, to package substrates with signal transmission paths relating to parasitic capacitance values.

### 2. Related Art

Semiconductor chips including integrated circuits may be encapsulated by a molding compound material to provide semiconductor packages. This is for protecting the semiconductor chips from an external environment such as a physical or chemical shock. The semiconductor chips embedded in the semiconductor packages may be electrically or signally connected to an external device or an external system through an interconnection structure included in a package substrate. The interconnection structure of the package substrate may include a plurality of circuit interconnections which are designed to have various shapes.

The interconnection structure may be comprised of chip bonding pads electrically connected to the semiconductor chip, land portions to which outer connectors are attached, and signal transmission lines electrically connecting the chip bonding pads to the land portions.

### SUMMARY

According to an embodiment, a package substrate may include first and second signal transmission lines having different lengths. The package substrate may include first and second conductive lands respectively connected to the first and second signal transmission lines. The package substrate may include a first capacitance adjustment pattern having a first overlap portion that overlaps with the first conductive land. The package substrate may include a second capacitance adjustment pattern having a second overlap portion that overlaps with the second conductive land. An overlap area of the first overlap portion may be different from an overlap area of the second overlap portion.

According to an embodiment, a package substrate may include a first signal transmission line and a second signal transmission line having different lengths. The package substrate may include a first capacitance adjustment pattern having a first overlap portion that overlaps with a portion of the first signal transmission line. The package substrate may include a second capacitance adjustment pattern having a second overlap portion that overlaps with a portion of the second signal transmission line. An overlap area of the first overlap portion may be different from an overlap area of the second overlap portion.

According to another embodiment, a package substrate may include conductive pads sequentially arrayed in a single column. The package substrate may include conductive lands arrayed in a matrix form. The package substrate may include signal transmission lines configured to respectively connect the conductive pads to the conductive lands and configured to have different lengths. The package substrate may include capacitance adjustment patterns having overlap portions that respectively overlap with the conductive lands. The overlap portions of the capacitance adjustment patterns may have different overlap areas.

According to an embodiment, a package substrate may include a first total signal path having a first parasitic capacitance value and a second total signal path having a second parasitic capacitance value different from the first parasitic capacitance value. The package substrate may include a first capacitance adjustment pattern disposed within the package substrate and configured to reduce the difference between the first and second parasitic capacitance values.

### BRIEF DESCRIPTION OF THE DRAWINGS

FIG. 1 is a plan view illustrating an interconnection structure of a package substrate according to an embodiment.

FIG. 2 is a cross-sectional view taken along a line Al-A1′ of FIG. 1.

FIG. 3 is an enlarged perspective view illustrating a portion ‘D1’ of FIG. 2.

FIG. 4 is a cross-sectional view taken along a line A2-A2′ of FIG. 1.

FIG. 5 is an enlarged perspective view illustrating a portion ‘D2’ of FIG. 4.

FIG. 6 is a cross-sectional view taken along a line A3-A3′ of FIG. 1.

FIG. 7 is an enlarged perspective view illustrating a portion ‘D3’ of FIG. 6.

FIGS. 8 and 9 are perspective views illustrating capacitance adjustment patterns of a package substrate according to an embodiment.

FIG. 10 is a block diagram illustrating an electronic system employing a memory card including a package substrate according to an embodiment.

FIG. 11 is a block diagram illustrating an electronic system including a package substrate according to an embodiment.

### DETAILED DESCRIPTION

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element, but not used to define only the element itself or to mean a particular sequence.

A semiconductor package may include electronic devices such as semiconductor chips or semiconductor dies. The semiconductor chips or the semiconductor dies may be obtained by separating a semiconductor substrate such as a wafer into a plurality of pieces using a die sawing process. The semiconductor chips may correspond to memory chips, logic chips (including application specific integrated circuits (ASIC) chips), or system-on-chips (SoC). The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The logic chips may include logic circuits which are integrated on the semiconductor substrate. The semiconductor package may be employed in communication systems such as mobile phones, electronic systems associated with biotechnology or health care, or wearable electronic systems.

In an interconnection structure of a package substrate included in the semiconductor package, signal transmission lines of the interconnection structure may have different lengths. In such a case, parasitic capacitance values of the signal transmission lines may also be different from each other. Accordingly, electrical signals transmitted through the signal transmission lines may exhibit different characteristics, for example, different delay times. This may lead to degradation of characteristics of the semiconductor package or may cause malfunction of the semiconductor package. Thus, it may be necessary to compensate for the parasitic capacitance values of the signal transmission lines to obtain uniform characteristics of the electrical signals transmitted through the signal transmission lines. The present disclosure may provide package substrates including capacitance adjustment patterns that compensate for the parasitic capacitance values of the signal transmission lines.

Various embodiments of the present disclosure will be described hereinafter with reference to the accompanying drawings. Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing.

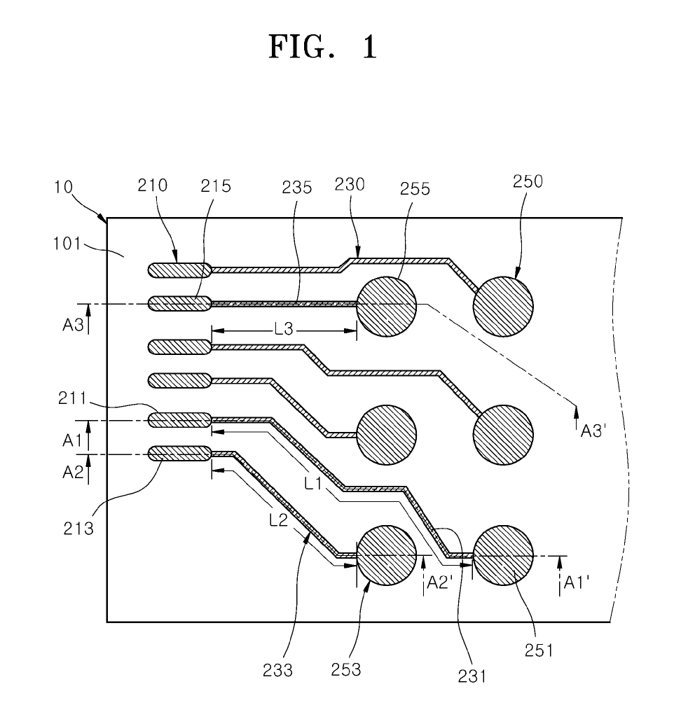

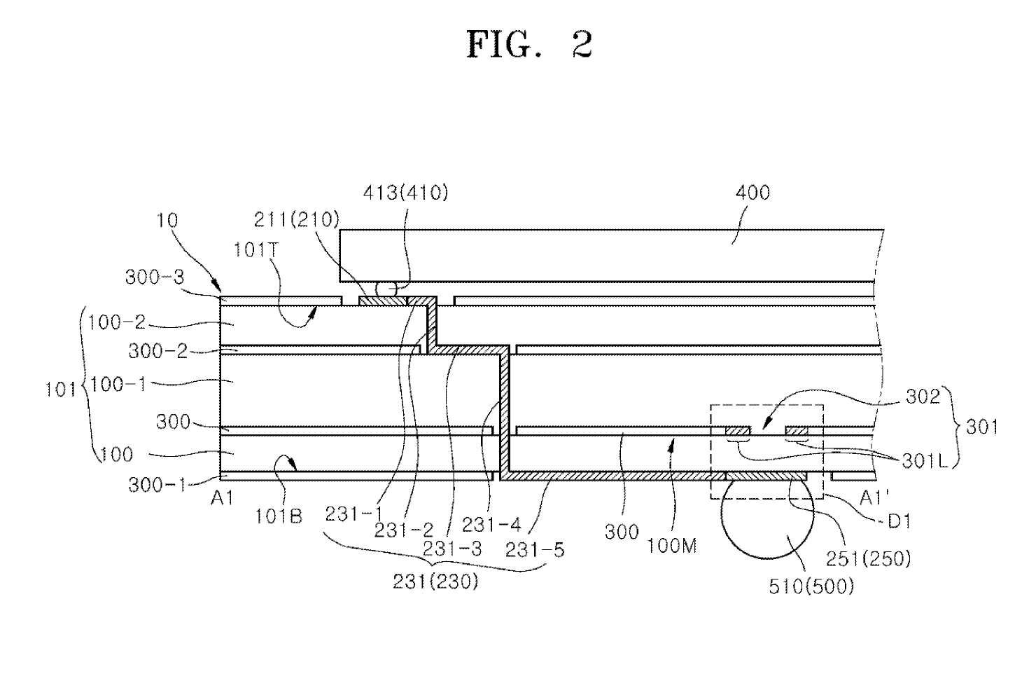

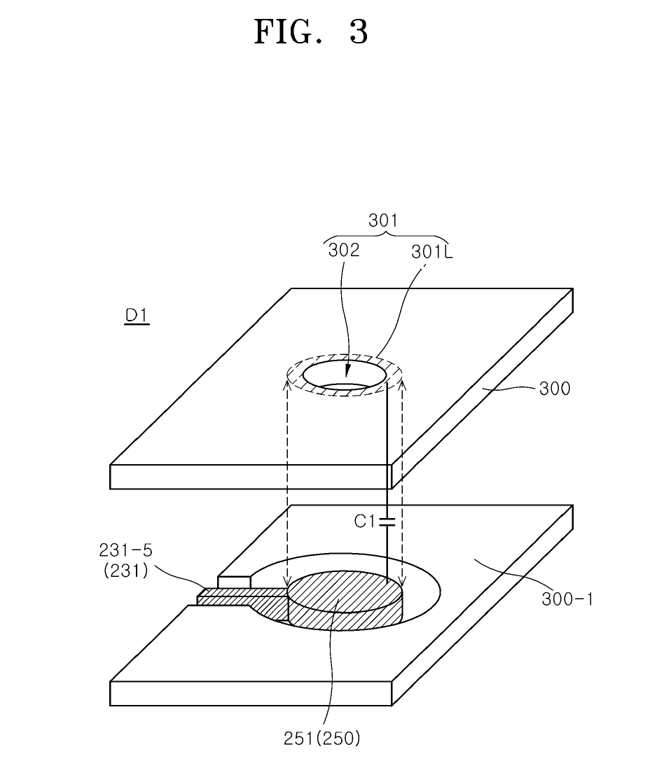

FIG. 1 is a plan view illustrating an interconnection structure of a package substrate 10 according to an embodiment. FIG. 2 is a cross-sectional view taken along a line Al-A1′ of FIG. 1, and FIG. 3 is an enlarged perspective view illustrating a portion ‘D’ of FIG. 2.

Referring to FIG. 1, the package substrate 10 may include the interconnection structure which is comprised of an array of conductive pads 210, an array of conductive lands 250, and signal transmission lines 230 connecting the conductive pads 210 to the conductive lands 250. For the purpose of ease and convenience in explanation, the conductive pads 210, the conductive lands 250 and the signal transmission lines 230 are illustrated in a single plane view of FIG. 1.

In an embodiment, the conductive pads 210 may be disposed at one level in a substrate body 101 of the package substrate 10, and the conductive lands 250 may be disposed at another level in the substrate body 101 of the package substrate 10 (see the cross-sectional view of FIG. 2). Each of the signal transmission lines 230 may be configured to include conductive trace patterns 231-1, 231-3 and 231-5 and conductive vias 231-2 and 231-4 for connecting the conductive trace patterns 231-1, 231-3 and 231-5 to each other. The conductive trace patterns 231-1, 231-3 and 231-5 may be conductive patterns which are located at different levels in the substrate body 101. The conductive vias 231-2 and 231-4 may be conductive patterns that substantially penetrate various layers constituting the substrate body 101.

As illustrated in FIG. 1, the conductive pads 210 may be sequentially disposed. The conductive pad 210 may be disposed in a single column. The conductive pads 210 may be disposed to be electrically connected to a semiconductor chip (400 of FIG. 2). The conductive pads 210 may correspond to bonding pads to which chip connectors (e.g., bonding wires) for electrically connecting the semiconductor chip 400 to the conductive pads 210 are coupled. In an embodiment, the conductive pads 210 may be bump pads (see FIG. 2). In such a case, the semiconductor chip 400 may be connected to the bump pads of the package substrate 10 through bumps 410. The conductive pads 210 may be disposed at positions that respectively face chip pads (not shown) of the semiconductor chip 400 which is electrically connected to the conductive pads 210. The chip pads (not shown) of the semiconductor chip 400 may be typically disposed in a column. Accordingly, the conductive pads 210 may be sequentially disposed in a single column, as illustrated in FIG. 1.

Outer connectors (not shown) may be attached to the conductive lands 250 to electrically connect a semiconductor chip mounted on the package substrate 10 to an external device or an external system. As illustrated in FIG. 2, the conductive lands 250 may correspond to ball lands to which ball connectors 500 are attached. Since the ball connectors 500 such as solder balls are respectively attached to the conductive lands 250, each of the conductive lands 250 may be disposed to have a planar area which is greater than a planar area of each conductive pad 210.

As illustrated in FIG. 1, the conductive lands 250 may be arrayed in a matrix form. The conductive lands 250 may be arrayed in at least two rows and at least two columns. Thus, the signal transmission lines 230 may have different routing lengths L1, L2 and L3. A length of each of the signal transmission lines 230 may be determined, substantially, according to a location of the conductive land 250 connected to each of the signal transmission lines 230. The routing lengths of the signal transmission lines 230 may be influenced by various factors, for example, a pitch of the conductive lands 250, a planar area of each conductive land 250, a pitch of the conductive pads 210, a planar area of each conductive pad 210, a size of a semiconductor chip mounted on the package substrate 10, and a size of a semiconductor package including the package substrate 10. A width of each of the signal transmission lines 230 may be less than a diameter of each of the conductive lands 250.

As illustrated in FIG. 1, a first conductive pad 211 of the conductive pads 210 may be connected to a first conductive land 251 of the conductive lands 250 through a first signal transmission line 231 of the signal transmission lines 230, and a second conductive pad 213 of the conductive pads 210 may be connected to a second conductive land 253 of the conductive lands 250 through a second signal transmission line 233 of the signal transmission lines 230. A third conductive pad 215 of the conductive pads 210 may be connected to a third conductive land 255 of the conductive lands 250 through a third signal transmission line 235 of the signal transmission lines 230. In such a case, the length L1 of the first signal transmission line 231 may be greater than the length L2 of the second signal transmission line 233, and the length L3 of the third signal transmission line 235 may be less than the length L2 of the second signal transmission line 233. Since the lengths L1, L2 and L3 of the first to third signal transmission lines 231, 233 and 235 are different from each other, parasitic capacitance values of the first to third signal transmission lines 231, 233 and 235 may also be different. Thus, electrical signals transmitted through the signal transmission lines 231, 233 and 235 may exhibit different characteristics, for example, different delay times. Accordingly, the present disclosure provides a package substrate including capacitance adjustment patterns that compensate for the parasitic capacitance values of the signal transmission lines 230.

Referring to FIG. 2, the package substrate 10 may have a four-layered structure. In some other embodiments, the package substrate 10 may have a multi-layered structure including two layers, three layers, or at least five layers. The package substrate 10 may include the substrate body 101 having a first dielectric layer 100, a second dielectric layer 100-1 and a third dielectric layer 100-2. The first conductive pad 211 may be disposed on a first surface 101T corresponding to a top surface of the substrate body 101. The first conductive land 251 may be disposed on a second surface 101B corresponding to a bottom surface of the substrate body 101 opposite to the semiconductor chip 400. A first ball connector 510 of the ball connectors 500 may be attached to the first conductive land 251.

The first signal transmission line 231 connecting the first conductive pad 211 to the first conductive land 251 may be disposed to substantially penetrate the substrate body 101. The first signal transmission line 231 may include the first conductive trace pattern 231-1, the first via 231-2, the second conductive trace pattern 231-3, the second via 231-4 and the third conductive trace pattern 231-5. The first conductive trace pattern 231-1, the first via 231-2, the second conductive trace pattern 231-3, the second via 231-4 and the third conductive trace pattern 231-5 may be illustrated as a single line corresponding to the first signal transmission line 231 when viewed from the plan view of FIG. 1.

The first conductive trace pattern 231-1 may be a portion connected to the first conductive pad 211 and may be disposed on the first surface 101T corresponding to a top surface of the third dielectric layer 100-2 opposite to the second dielectric layer 100-1. The second conductive trace pattern 231-3 may be disposed between the second and third dielectric layers 100-1 and 100-2. The first via 231-2 may substantially penetrate the third dielectric layer 100-2 to connect the first conductive trace pattern 231-1 to the second conductive trace pattern 231-3. The third conductive trace pattern 231-5 may be disposed on the second surface 101B corresponding to a bottom surface of the first dielectric layer 100 opposite to the second dielectric layer 100-1. The third conductive trace pattern 231-5 may extend to be in contact with the first conductive land 251. The second via 231-4 may substantially penetrate the first and second dielectric layers 100 and 100-1 to connect the second conductive trace pattern 231-3 to the third conductive trace pattern 231-5.

A first capacitance adjustment pattern 301 may be disposed to face the first conductive land 251. The first capacitance adjustment pattern 301 may include a first overlap portion 301L and a first opening portion 302. The first overlap portion 301L of the first capacitance adjustment pattern 301 may substantially and vertically overlap with the first conductive land 251. The first overlap portion 301L may partially overlap with first conductive land 251. The first opening portion 302 may be an empty space corresponding to a void influencing an overlap area between the first capacitance adjustment pattern 301 and the first conductive land 251, as illustrated in FIG. 3. The first opening portion 302 may be disposed to substantially and vertically overlap with the first conductive land 251. If a size or an area of the first opening portion 302 varies, a size or an area of the first overlap portion 301L may also vary. Thus, the first opening portion 302 may correspond to a pattern influencing a planar area or a width of the first overlap portion 301L.

In FIG. 3, the first opening portion 302 is illustrated to have a circular shape. The first opening portion 302 having a circular shape may be disposed so that an entire portion of the first opening portion 302 fully overlaps with the first conductive land 251. Thus, the first overlap portion 301L vertically overlapping with the first conductive land 251 may surround the first opening portion 302 to have a ring shape. In an embodiment, the first opening portion 302 may be modified to have a stripe shape, a rectangular shape or a mesh shape. In either case, the first opening portion 302 may be located so that an entire portion of an edge of the first conductive land 251 fully overlaps with the first overlap portion 301L regardless of a shape of the first opening portion 302. In such a case, even though the first opening portion 302 is misaligned with the first conductive land 251 within the range of an allowable process tolerance, an overlap area between the first capacitance adjustment pattern 301 (i.e., the first overlap portion 301L) and the first conductive land 251 may maintain to have a substantially constant value.

Referring again to FIG. 2, the first capacitance adjustment pattern 301 may be disposed on a third surface 100M corresponding to a surface of the first dielectric layer 100 opposite to the first conductive land 251. The first overlap portion 301L of the first capacitance adjustment pattern 301 may be comprised of a conductive material. The first capacitance adjustment pattern 301 may be a portion of a first reference layer 300. The first reference layer 300 may be disposed between the first dielectric layer 100 and the second dielectric layer 100-1. The first capacitance adjustment pattern 301 may be provided by patterning the first reference layer 300 to form the first opening portion 302. The first opening portion 302 may be filled with a dielectric material, for example, a portion of the second dielectric layer 100-1.

The first reference layer 300 may be a ground plane to which a ground voltage is applied. A second reference layer 300-1 may be disposed on the second surface 101B corresponding to the bottom surface of the first dielectric layer 100 opposite to the first reference layer 300. The second reference layer 300-1 may be disposed to be spaced apart from the first conductive land 251 and the third conductive trace pattern 231-5. A third reference layer 300-2 may be disposed between the second dielectric layer 100-1 and the third dielectric layer 100-2, as illustrated in FIG. 2. The third reference layer 300-2 may be a power plane to which a power supply voltage is applied. A fourth reference layer 300-3 may be disposed on the first surface 101T corresponding to the top surface of the third dielectric layer 100-2 opposite to the third reference layer 300-2. The fourth reference layer 300-3 may be disposed to be spaced apart from the first conductive pad 211. The first to fourth reference layers 300, 300-1, 300-2 and 300-3 may be conductive layers which are disposed to be spaced part from the signal transmission lines 230.

Referring again to FIG. 3, the first conductive land 251 and the first overlap portion 301L of the first capacitance adjustment pattern 301 may constitute a capacitor together with the first dielectric layer 100 disposed between the first conductive land 251 and the first overlap portion 301L. The capacitor comprised of the first conductive land 251 and the first overlap portion 301L may correspond to a parasitic capacitor of the first conductive land 251 and may have a first parasitic capacitance value C1. An additional parasitic capacitance component of the first conductive land 251 may also exist between the first conductive land 251 and the second reference layer 300-1 laterally spaced apart from the first conductive land 251. Since a thickness of the first conductive land 251 is about several micrometers to about ten micrometers while a diameter of the first conductive land 251 is about several hundreds of micrometers, the additional parasitic capacitance component corresponding to a lateral parasitic capacitance component of the first conductive land 251 may have a relatively low value as compared with the first parasitic capacitance value C1 corresponding to a vertical parasitic capacitance component of the first conductive land 251. Accordingly, only the first parasitic capacitance value C1 may be considered as the parasitic capacitance value of the first conductive land 251.

The first parasitic capacitance value C1 may be dominantly determined by a vertical overlap area between the first capacitance adjustment pattern 301 and the first conductive land 251, that is, by a planar area of the first overlap portion 301L. Each of the conductive lands 250 may have substantially the same size (e.g., the same planar area) to respectively attach the ball connectors 500 having the same size (e.g., the same diameter) to the conductive lands 250. Since the conductive lands 250 have substantially the same planar area, the first parasitic capacitance value C1 may change according to variation of a planar area of the first overlap portion 301L. If the planar area of the first overlap portion 301L increases, the first parasitic capacitance value C1 may also increase. That is, if a size of the first opening portion 302 is reduced, the first parasitic capacitance value C1 may increase. On the contrary, if a size of the first opening portion 302 increases to reduce a planar area of the first overlap portion 301L, the first parasitic capacitance value C1 may decrease. A planar area of the first overlap portion 301L may vary if a planar area occupied by the first opening portion 302 in the first capacitance adjustment pattern 301 is changed.

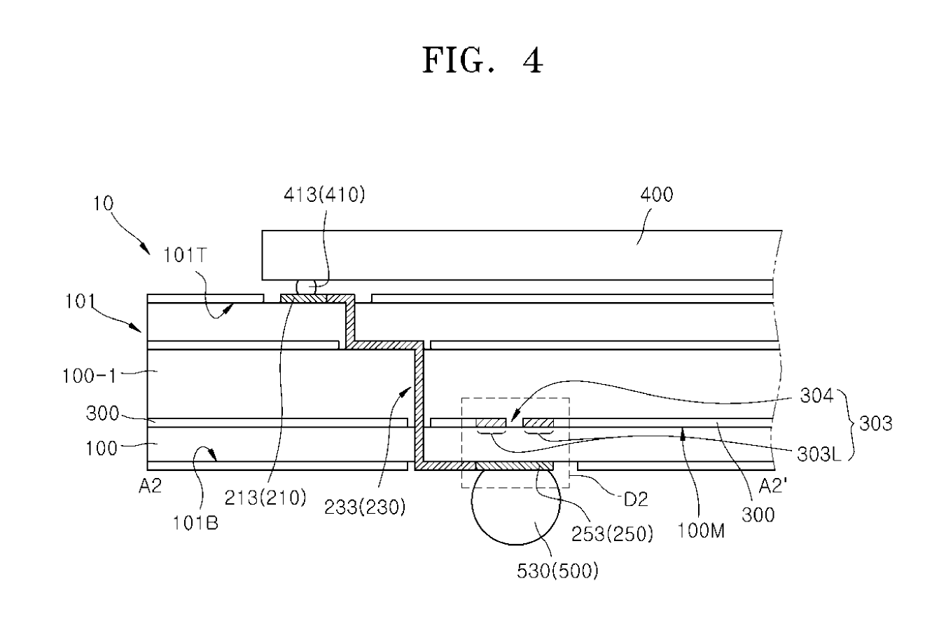

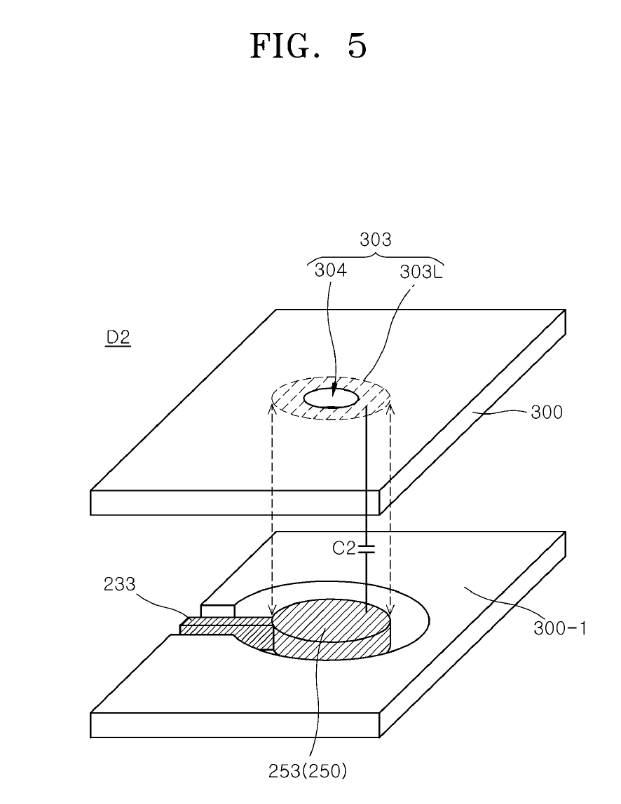

FIG. 4 is a cross-sectional view taken along a line A2-A2′ of FIG. 1, and FIG. 5 is an enlarged perspective view illustrating a portion ‘D2’ of FIG. 4.

Referring to FIGS. 4 and 5, the second conductive pad 213 may be disposed on the first surface 101T corresponding to the top surface of the substrate body 101 of the package substrate 10. The second conductive land 253 may be disposed on the second surface 101B of the substrate body 101. A second ball connector 530 of the ball connectors 500 may be attached to the second conductive land 253. The second signal transmission line 233 may be disposed in and on the substrate body 101 to connect the second conductive pad 213 to the second conductive land 253.

A second capacitance adjustment pattern 303 may be disposed to face the second conductive land 253. The second capacitance adjustment pattern 303 may include a second overlap portion 303L and a second opening portion 304 defining the second overlap portion 303L. The second opening portion 304 may be disposed so that an entire portion of the second opening portion 304 fully overlaps with the second conductive land 253. Thus, the second overlap portion 303L vertically overlapping with the second conductive land 253 may surround the second opening portion 304 to have a ring shape. The second opening portion 304 may be filled with the dielectric material, for example, a portion of the second dielectric layer 100-1.

In an embodiment, the second opening portion 304 may be modified to have a stripe shape, a rectangular shape or a mesh shape. In any case, the second opening portion 304 may be located so that an entire portion of an edge of the second conductive land 253 fully overlaps with the second overlap portion 303L regardless of a shape of the second opening portion 304. In such a case, even though the second opening portion 304 is misaligned with the second conductive land 253 within the range of an allowable process tolerance, an overlap area between the second capacitance adjustment pattern 303 (i.e., the second overlap portion 303L) and the second conductive land 253 may maintain to have a substantially constant value.

A planar area of the second overlap portion 303L may be greater than a planar area of the first overlap portion (301L of FIG. 3). The second capacitance adjustment pattern 303 may also be disposed on the third surface 100M of the first dielectric layer 100. The second overlap portion 303L of the second capacitance adjustment pattern 303 may include a conductive material. The second capacitance adjustment pattern 303 may also correspond to a portion of the first reference layer 300.

The second conductive land 253 and the second overlap portion 303L of the second capacitance adjustment pattern 303 may constitute a capacitor together with the first dielectric layer 100 disposed between the second conductive land 253 and the second overlap portion 303L. The capacitor comprised of the second conductive land 253 and the second overlap portion 303L may correspond to a parasitic capacitor of the second conductive land 253 and may have a second parasitic capacitance value C2. The second parasitic capacitance value C2 may be dominantly determined by a vertical overlap area between the second capacitance adjustment pattern 303 and the second conductive land 253, that is, by a planar area of the second overlap portion 303L. Since a planar area of the second overlap portion 303L is greater than a planar area of the first overlap portion (301L of FIG. 3), the second parasitic capacitance value C2 may be greater than the first parasitic capacitance value C1. A thickness of the second conductive land 253 is about several micrometers to about ten micrometers while a diameter of the second conductive land 253 is about several hundreds of micrometers. Thus, a lateral parasitic capacitance component of the second conductive land 253 may have a relatively low value as compared with the second parasitic capacitance value C2 corresponding to a vertical parasitic capacitance component of the second conductive land 253. Accordingly, only the second parasitic capacitance value C2 may be considered as the parasitic capacitance value of the second conductive land 253.

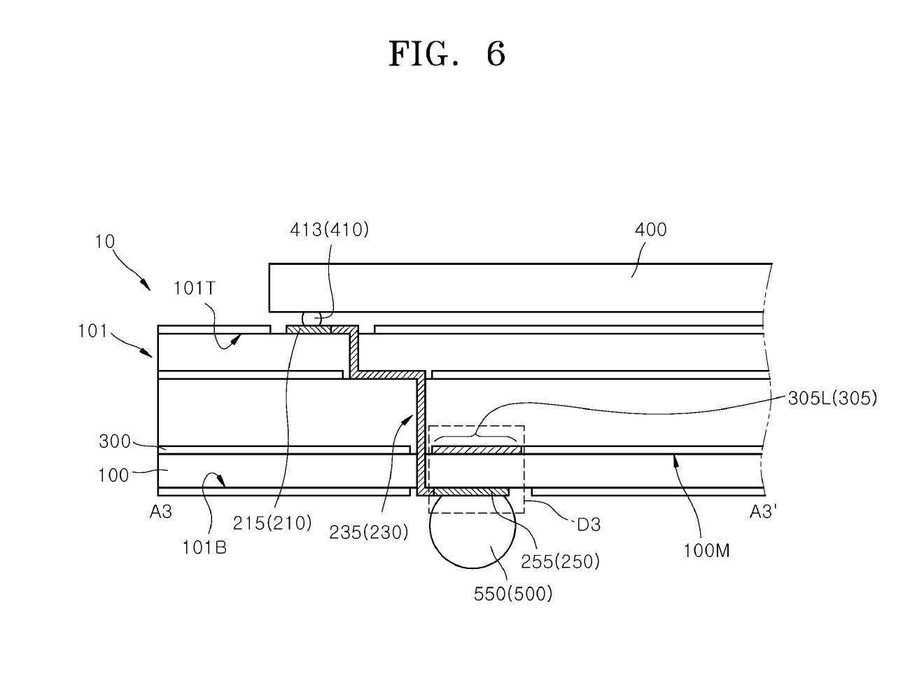

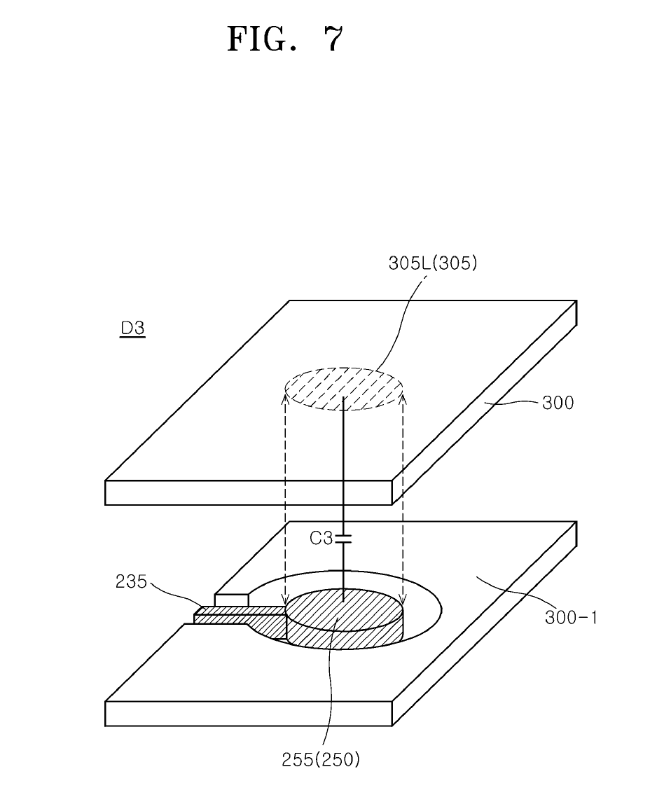

FIG. 6 is a cross-sectional view taken along a line A3-A3′ of FIG. 1, and FIG. 7 is an enlarged perspective view illustrating a portion ‘D3’ of FIG. 6.

Referring to FIGS. 6 and 7, the third conductive pad 215 may be disposed on the first surface 101T corresponding to the top surface of the substrate body 101 of the package substrate 10. The third conductive land 255 may be disposed on the second surface 101B of the substrate body 101. A third ball connector 550 of the ball connectors 500 may be attached to the third conductive land 255. The third signal transmission line 235 may be disposed in and on the substrate body 101 to connect the third conductive pad 215 to the third conductive land 255.

A third capacitance adjustment pattern 305 may be disposed to face the third conductive land 255. The third capacitance adjustment pattern 305 may include a third overlap portion 305L. The third overlap portion 305L of the third capacitance adjustment pattern 305 may be formed to vertically and fully overlap with an entire portion of the third conductive land 255. The third capacitance adjustment pattern 305 may be provided without any opening portion. The third overlap portion 305L may be provided to have a planar area which is greater than a planar area of the second overlap portion (303L of FIG. 5).

The third capacitance adjustment pattern 305 may also be disposed on the third surface 100M of the first dielectric layer 100. The third overlap portion 305L of the third capacitance adjustment pattern 305 may include a conductive material. The third capacitance adjustment pattern 305 may also correspond to a portion of the first reference layer 300. The first, second and third capacitance adjustment patterns 301, 303 and 305 may correspond to portions of the same conductive layer, for example, the first reference layer 300.

The third conductive land 255 and the third overlap portion 305L of the third capacitance adjustment pattern 305 may constitute a capacitor together with the first dielectric layer 100 disposed between the third conductive land 255 and the third overlap portion 305L. The capacitor comprised of the third conductive land 255 and the third overlap portion 305L may correspond to a parasitic capacitor of the third conductive land 255 and may have a third parasitic capacitance value C3. The third parasitic capacitance value C3 may be dominantly determined by a vertical overlap area between the third capacitance adjustment pattern 305 and the third conductive land 255, that is, by a planar area of the third overlap portion 305L. Since a planar area of the third overlap portion 305L is greater than a planar area of the second overlap portion (303L of FIG. 5), the third parasitic capacitance value C3 may be greater than the second parasitic capacitance value C2. A thickness of the third conductive land 255 is about several micrometers to about ten micrometers while a diameter of the third conductive land 255 is about several hundreds of micrometers. Thus, a lateral parasitic capacitance component of the third conductive land 255 may have a relatively low value as compared with the third parasitic capacitance value C3 corresponding to a vertical parasitic capacitance component of the third conductive land 255. Accordingly, only the third parasitic capacitance value C3 may be considered as the parasitic capacitance value of the third conductive land 255.

Referring to FIGS. 3, 5 and 7, the first, second and third conductive lands 251, 253 and 255 may have substantially the same planar area and substantially the same shape. In contrast, the first, second and third overlap portions 301L, 303L and 305L of the first, second and third capacitance adjustment patterns 301, 303 and 305 may have different planar areas. The first, second and third overlap portions 301L, 303L and 305L may be formed so that planar areas of the first, second and third overlap portions 301L, 303L and 305L sequentially have higher values. Thus, the third parasitic capacitance value C3 may be greater than the second parasitic capacitance value C2, and the second parasitic capacitance value C2 may be greater than the first parasitic capacitance value C1. That is, the third, second and first parasitic capacitance values C3, C2 and C1 may be different from each other. For example, the third, second and first parasitic capacitance values C3, C2 and C1 may sequentially have lower values. The parasitic capacitors having the third, second and first parasitic capacitance values C3, C2 and C1, which are different from each other, may be used to compensate for parasitic capacitance values of the third, second and first signal transmission lines (235, 233 and 231 of FIG. 1) to reduce the differences between the parasitic capacitance values of the third, second and first signal transmission lines (235, 233 and 231 of FIG. 1).

As illustrated in FIG. 1, the first signal transmission line 231 may have the first length L1 which is greater than the second and third lengths L2 and L3 of the second and third signal transmission lines 233 and 235. Thus, the first signal transmission line 231 may have a fourth parasitic capacitance value C4 corresponding to substantially the highest parasitic capacitance value among parasitic capacitance values of the first, second and third signal transmission lines 231, 233 and 235. The fourth parasitic capacitance value C4 may correspond to a parasitic capacitance value of the first signal transmission line 231 when the first capacitance adjustment pattern 301 is absent. The second signal transmission line 233 may have the second length L2 which is less than the first length L1 of the first signal transmission line 231. Thus, the second signal transmission line 233 may have a fifth parasitic capacitance value C5 which is substantially less than the fourth parasitic capacitance value C4. The fifth parasitic capacitance value C5 may correspond to a parasitic capacitance value of the second signal transmission line 233 when the second capacitance adjustment pattern 303 is absent. The third signal transmission line 235 may have the third length L3 which is less than the first and second lengths L1 and L2 of the first and second signal transmission lines 231 and 233. Thus, the third signal transmission line 235 may have a sixth parasitic capacitance value C6 corresponding to the lowest parasitic capacitance value among the parasitic capacitance values of the first, second and third signal transmission lines 231, 233 and 235. The sixth parasitic capacitance value C6 may correspond to a parasitic capacitance value of the third signal transmission line 235 when the third capacitance adjustment pattern 305 is absent.

The first, second and third parasitic capacitance values C1, C2 and C3 may compensate for differences between the fourth, fifth and sixth parasitic capacitance values C4, C5 and C6. Thus, all of total signal paths including the signal transmission lines 230 and the conductive lands 250 may have substantially the same parasitic capacitance value. Even though the signal transmission lines 230 have different lengths, all of the total signal paths including the signal transmission lines 230 and the conductive lands 250 may have substantially the same parasitic capacitance value because of the presence of the capacitance adjustment patterns. As a result, a semiconductor package employing the package substrate 10 may exhibit improved characteristics.

In an embodiment, a first capacitance difference of +0.07 picofarads (C4-C5) may exist between the fourth parasitic capacitance value C4 corresponding to a parasitic capacitance value of the first signal transmission line 231 and the fifth parasitic capacitance value C5 corresponding to a parasitic capacitance value of the second signal transmission line 233. In such a case, the first and second capacitance adjustment patterns 301 and 303 may be designed so that a second capacitance difference of −0.07 picofarads (C1-C2) exists between the first parasitic capacitance value C1 corresponding to a parasitic capacitance value of the first conductive land 251 and the second parasitic capacitance value C2 corresponding to a parasitic capacitance value of the second conductive land 253. As a result, since the first capacitance difference is offset by the second capacitance difference, a parasitic capacitance value of the first total signal path including the first signal transmission line 231 and the first conductive land 251 may be substantially equal to a parasitic capacitance value of the second total signal path including the second signal transmission line 233 and the second conductive land 253. That is, a couple of parasitic capacitors (not shown) may be respectively and equivalently coupled to the first signal transmission line 231 and the second signal transmission line 233 to provide the first capacitance difference (C4-C5) between the couple of parasitic capacitors. In addition, another couple of parasitic capacitors (not shown) may be respectively and equivalently coupled to the first conductive land 251 and the second conductive land 253 to provide the second capacitance difference (C1-C2) between the other couple of parasitic capacitors, which is capable of offsetting the first capacitance difference.

As described above, a parasitic capacitance value of the first total signal path including the first signal transmission line 231 and the first conductive land 251 may be substantially equal to a parasitic capacitance value of the second total signal path including the second signal transmission line 233 and the second conductive land 253. That is, a difference between the parasitic capacitance value of the first total signal path (including the first signal transmission line 231 and the first conductive land 251) and the parasitic capacitance value of the second total signal path (including the second signal transmission line 233 and the second conductive land 253) may be substantially reduced due to the presence of the first and second capacitance adjustment patterns 301 and 303.

If the first, second and third parasitic capacitance values C1, C2 and C3 are appropriately adjusted, the first, second and third total signal paths including the first to third signal transmission lines 231, 233 and 235 and the first to third conductive lands 251, 253 and 255 may have substantially the same parasitic capacitance value. That is, if the planar areas of the first to third overlap portions 301L, 303L and 305L are appropriately adjusted, differences between the fourth to sixth parasitic capacitance values C4, C5 and C6 may be compensated. As a result, the first to third total signal paths including the first to third signal transmission lines 231, 233 and 235 and the first to third conductive lands 251, 253 and 255 may have substantially the same parasitic capacitance value.

As illustrated in FIG. 1, the package substrate 10 according to an embodiment may include the conductive pads 210 sequentially arrayed in a single column and the conductive lands 250 disposed in a matrix form. The package substrate 10 may further include the signal transmission lines 230 that respectively connect the conductive pads 210 to the conductive lands 250 and have different lengths. In addition, the package substrate 10 may further include the capacitance adjustment patterns having the overlap portions that respectively overlap with the conductive lands 250. In such a case, the overlap portions of the capacitance adjustment patterns may be designed to have different overlap areas. The conductive lands 250 may have substantially the same size to attach the ball connectors 500 having a uniform size to the conductive lands 250. Since the conductive lands 250 have substantially the same planar area, the parasitic capacitance values of the conductive lands 250 may be different if the overlap portions of the capacitance adjustment patterns are designed to have different planar areas.

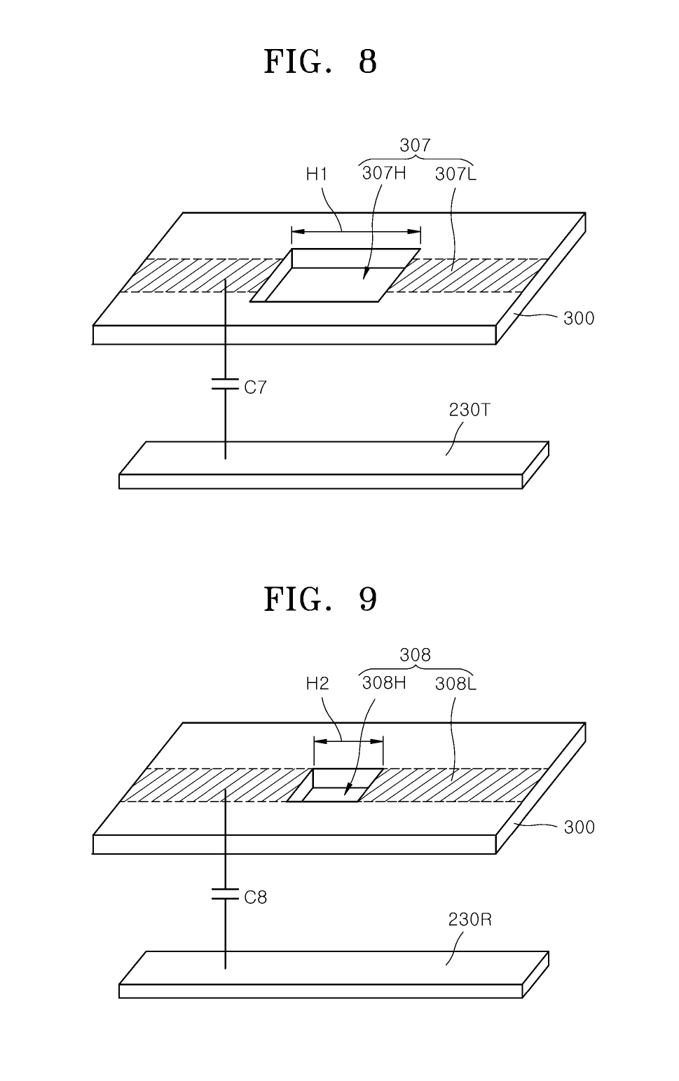

FIGS. 8 and 9 are perspective views illustrating fourth and fifth capacitance adjustment patterns 307 and 308 of a package substrate according to an embodiment, respectively.

Referring to FIG. 8, the fourth capacitance adjustment pattern 307 may be disposed to overlap with a fourth trace pattern 230T. The fourth trace pattern 230T may correspond to a portion of the first signal transmission line (231 of FIG. 1). For example, the fourth trace pattern 230T may be a portion of the third trace pattern (231-5 of FIG. 2) of the first signal transmission line (231 of FIG. 1). The fourth capacitance adjustment pattern 307 may include a fourth overlap portion 307L and a fourth opening portion 307H. The fourth opening portion 307H may be a hole or a void which has a first width H1. The fourth capacitance adjustment pattern 307 may be disposed on the third surface (100M of FIG. 2) corresponding to a surface of the first dielectric layer 100, but the present disclosure is not limited thereto. The fourth overlap portion 307L may be a portion of the first reference layer (300 of FIG. 2), but the present disclosure is not limited thereto.

A parasitic capacitor having a seventh parasitic capacitance value C7 may exist between the fourth trace pattern 230T and the fourth overlap portion 307L of the fourth capacitance adjustment pattern 307. The seventh parasitic capacitance value C7 may be determined by an area of the fourth capacitance adjustment pattern 307 vertically overlapping with the fourth trace pattern 230T, that is, a planar area of the fourth overlap portion 307L. A planar area of the fourth overlap portion 307L may be determined by the first width H1 of the fourth opening portion 307H.

Referring to FIG. 9, the fifth capacitance adjustment pattern 308 may be disposed to overlap with a fifth trace pattern 230R. The fifth trace pattern 230R may be a portion of the second signal transmission line (233 of FIG. 1). For example, the fifth trace pattern 230R may be a portion which is connected to the second conductive land (253 of FIG. 4), but the present disclosure is not limited thereto. The fifth capacitance adjustment pattern 308 may include a fifth overlap portion 308L and a fifth opening portion 308H. The fifth capacitance adjustment pattern 308 may be disposed on the third surface (100M of FIG. 4) corresponding to a surface of the first dielectric layer 100, but the present disclosure is not limited thereto. The fifth overlap portion 308L may be a portion of the first reference layer (300 of FIG. 2), but the present disclosure is not limited thereto.

The fifth opening portion 308H may be a hole or a void having a second width H2 which is less than the first width H1. A parasitic capacitor having an eighth parasitic capacitance value C8 may exist between the fifth trace pattern 230R and the fifth overlap portion 308L of the fifth capacitance adjustment pattern 308.

In an embodiment, it may be assumed that each of the fourth and fifth trace patterns 230T and 230R has a width and a length that are equal to each other. In such a case, since the second width H2 of the fifth opening portion 308H is less than the first width H1 of the fourth opening portion 307H, a planar area of the fourth overlap portion (307L of FIG. 8) may be less than a planar area of the fifth overlap portion 308L. Thus, the seventh parasitic capacitance value (C7 of FIG. 8) may be less than the eighth parasitic capacitance value C8.

In an embodiment, the fourth trace pattern 230T may be considered as a portion of the first signal transmission line (231 of FIG. 1) and the fifth trace pattern 230R may be considered as a portion of the second signal transmission line (233 of FIG. 1). In such a case, since a length (i.e., the first length L1) of the first signal transmission line 231 is greater than a length (i.e., the second length L2) of the second signal transmission line 233, a parasitic capacitance value of the first signal transmission line 231 is greater than a parasitic capacitance value of the second signal transmission line 233. However, the seventh parasitic capacitance value C7 provided by the fourth capacitance adjustment pattern 307 may be less than the eighth parasitic capacitance value C8 provided by the fifth capacitance adjustment pattern 308. Thus, a difference between a total parasitic capacitance value of the first signal transmission line 231 and a total parasitic capacitance value of the second signal transmission line 233 may be reduced. Thus, for example, a total parasitic capacitance value of the first signal transmission line 231 may be substantially equal to a total parasitic capacitance value of the second signal transmission line 233.

As described above, a package substrate according to an embodiment may compensate for parasitic capacitance values of signal transmission lines having different lengths to reduce differences between total parasitic capacitance values of the signal transmission lines. Thus, electrical characteristics of signal pins connected to the signal transmission lines may be improved to be uniform. As a result, it may be possible to improve electrical characteristics of semiconductor packages employing the package substrate according to the embodiments.

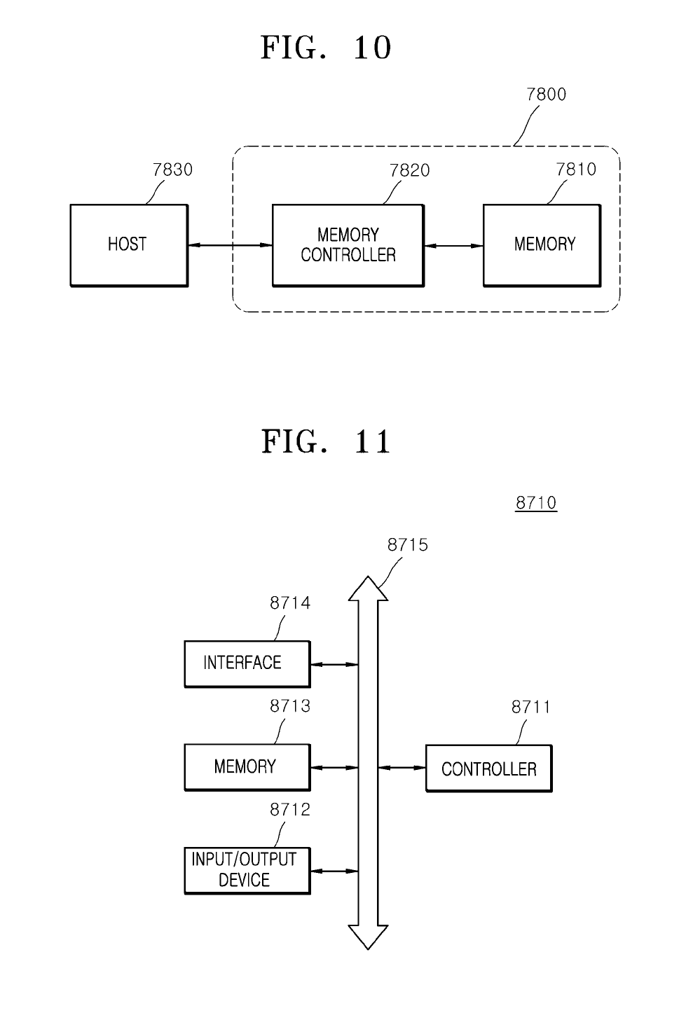

FIG. 10 is a block diagram illustrating an electronic system including a memory card 7800 employing at least one of the package substrates according to the embodiments. The memory card 7800 includes a memory 7810 such as a nonvolatile memory device, and a memory controller 7820. The memory 7810 and the memory controller 7820 may store data or read out the stored data. At least one of the memory 7810 and the memory controller 7820 may include at least one of the package substrates according to the embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

FIG. 11 is a block diagram illustrating an electronic system 8710 including at least one of the package substrates according to the embodiments. The electronic system 8710 may include a controller 8711, an input/output device 8712 and a memory 8713. The controller 8711, the input/output device 8712 and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the package substrates according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) or Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A package substrate comprising:
a first signal transmission line and a second signal transmission line having different lengths;
a first conductive land and a second conductive land connected to the first and second signal transmission lines, respectively;
a first capacitance adjustment pattern having a first overlap portion that overlaps with the first conductive land; and
a second capacitance adjustment pattern having a second overlap portion that overlaps with the second conductive land,
wherein an overlap area of the first overlap portion is different from an overlap area of the second overlap portion.

2. The package substrate of claim 1,
wherein the first signal transmission line has a length which is greater than a length of the second signal transmission line; and
wherein the first overlap portion of the first capacitance adjustment pattern has an overlap area which is less than an overlap area of the second overlap portion of the second capacitance adjustment pattern.

3. The package substrate of claim 1, wherein the first capacitance adjustment pattern has a first opening portion that determines an overlap area of the first overlap portion.

4. The package substrate of claim 3, wherein the first opening portion is filled with a dielectric material.

5. The package substrate of claim 3, wherein the first opening portion is located to substantially and vertically overlap with the first conductive land.

6. The package substrate of claim 3, wherein an entire portion of the first opening portion is located to fully overlap with the first conductive land.

7. The package substrate of claim 3,
wherein the second capacitance adjustment pattern has a second opening portion that determines an overlap area of the second overlap portion; and
wherein a width of the second opening portion is less than a width of the first opening portion.

8. The package substrate of claim 3, wherein the second overlap portion of the second capacitance adjustment pattern fully overlaps with an entire portion of the second conductive land.

9. The package substrate of claim 1, wherein the first overlap portion of the first capacitance adjustment pattern vertically and partially overlaps with the first conductive land.

10. The package substrate of claim 1, wherein the first overlap portion of the first capacitance adjustment pattern and the second overlap portion of the second capacitance adjustment pattern are portions of the same conductive layer.

11. The package substrate of claim 1, wherein the first conductive land corresponds to a ball land to which a ball connector is attached.

12. The package substrate of claim 1, wherein the first and second conductive lands have substantially the same planar area.

13. The package substrate of claim 1,
wherein a difference between a parasitic capacitance value of the first signal transmission line and a parasitic capacitance value of the second signal transmission line has a first capacitance difference value; and
wherein a difference between a parasitic capacitance value of the first conductive land and a parasitic capacitance value of the second conductive land has a second capacitance difference value for offsetting the first capacitance difference value.

14. A package substrate comprising:
a first signal transmission line and a second signal transmission line having different lengths;
a first capacitance adjustment pattern having a first overlap portion that overlaps with a portion of the first signal transmission line; and
a second capacitance adjustment pattern having a second overlap portion that overlaps with a portion of the second signal transmission line,
wherein an overlap area of the first overlap portion is different from an overlap area of the second overlap portion.

15. A package substrate comprising:
a first total signal path having a first parasitic capacitance value and a second total signal path having a second parasitic capacitance value different from the first parasitic capacitance value; and
a first capacitance adjustment pattern disposed within the package substrate and configured to reduce the difference between the first and second parasitic capacitance values.

16. The package substrate of claim 15,
wherein the first total signal path includes a first signal transmission line coupled to a first conductive land, and
wherein the first capacitance adjustment pattern includes an overlap portion overlapping with the first signal transmission line.

17. The package substrate of claim 15,
wherein the first total signal path includes a first signal transmission line coupled to a first conductive land, and
wherein the first capacitance adjustment pattern includes an overlap portion overlapping with the first conductive land.

18. The package substrate of claim 15,
wherein the first total signal path includes a first signal transmission line coupled to a first conductive land,
wherein the second total signal path includes a second signal transmission line coupled to a second conductive land,
wherein a length of the first signal transmission line is different from a length of the second signal transmission line, and
wherein a planar area of the first and second conductive lands are substantially the same.

19. The package substrate of claim 15,
wherein a length of the first total signal path is less than a length of the second total signal path, and wherein the first capacitance adjustment pattern includes an
overlap portion overlapping with the first total signal path.

20. The package substrate of claim 15,
wherein the first capacitance adjustment pattern includes an overlap portion overlapping with the first total signal path, and
wherein to reduce a larger difference, rather than a smaller difference, between the first and second parasitic capacitance values a larger size, rather than a smaller size, of a planar area of the overlap portion is included in the first capacitance adjustment pattern, and to reduce a smaller difference, rather than a lager difference, between the first and second parasitic capacitance values a smaller size, rather than a larger size, of the planar area of the overlap portion is included in the first capacitance adjustment pattern.
